(19) United States
(12) Patent Application Publication
(10) Pub. No.: US 2003/0123220 A1
(43) Pub. Date: Jul. 3, 2003

(54) Computer card reader adapting rack

(75) Inventor: Cheng Yu Huang, Taipei (TW)

Correspondence Address: TROXELL LAW OFFICE PLLC, SUITE 1404, 5205 LEESBURG PIKE, FALLS CHURCH, VA, 22041, US

(73) Assignee: Cheng Yu Huang and Enermax Technology Corporation

(21) Appl. No.: 10/097,941

(22) Filed: Mar. 15, 2002

(30) Foreign Application Priority Data
Dec. 27, 2001 (TW) 090223053

(51) Int. Cl. H05K 5/00

(52) U.S. Cl. 361/685; 361/684

(57) ABSTRACT

A computer card reader adapting rack is disclosed for installing a card reader so that data can be read from and written to a memory card in the card reader. The computer card reader adapting rack comprises a support seat, a card reading circuit element, a fixing panel, and an upper cover. The support seat is a box having a size like a 3.5 inches floppy disk. A front side of the support seat is fixed with a panel having a memory slot. An upper side of the support seat is fixed with an upper cover. Moreover, the support seat are installed with respective auxiliary frames and the front side of the support seat has a connecting plate has a window for combining the panel, thereby, the computer card reader adapting rack is used at one of 5.25 disk slots and 3.5 inches disk slots.

### BACKGROUND OF THE INVENTION

1. Field of the Invention

The present invention relates to computer peripheral devices, and particularly to a computer card reader adapting rack which can be installed to a computer casing for installing a card reader.

2. Description of the Related Art

Hard disks, soft disks, and compact disks are popular computer storing medium. Computers read data from and write data to these disks through disk drives. In general, hard disk drive is retained in a computer mainframe for fixing a hard disk, while the hard disk drive is portable through a mobile rack. However, since it is heavy and has a large weight and thus it is not suitable as a portable storage medium. Therefore, soft disks and compact disks are most frequently used storage mediums, but the capacity of a soft disk is small and in general, the compact disk is a write-once device. It can not be written repeatedly. Moreover, if it is desired to write data into a compact disk, a CD recorder is necessary, while the recorder is expensive and not suitable for being carried out.

Due to above mentioned defects of the prior art storage medium, manufacturer has developed memory cards with sufficient capacities and a small volume, such as C F (Compact Flash) • S D• M M C • Memory-stick & Smart-media, etc. Currently memory cards are widely used in digital cameras, MP3, and other computer peripherals; the memory cards can be accessed through an external card reader of a computer mainframe or a portable computer, generally, flash elements are existed in a card reader. Thereby, data can be stored in a memory card and thus is carried out.

Currently, the memory card reader is not a standard equipment, such as a floppy disk drive, a hard disk drive or a compact disk drive, which can be directly installed to a disk rack of a computer casing.

Accordingly, the object of the present invention is to provide a computer card reader adapting rack, wherein a card reader with a card reader circuit having flash head for reading and writing data is designed to be fixed at the disk rack of a computer casing. Thereby, it can be used as a standard equipment of computer peripherals.

The computer card reader adapting rack of the present invention can be installed to a disk rack of an old type or a new type computer. In general, the casing of a computer has two disk slots for 3.25 inches disk and 5.25 disks. 5.25 inches disk slots are used for hard disk drive box, mobile racks, and compact disk drive box, which can slide into the slots and then are fixed in the slot by using screws. Currently, the 3.5 inches disk slot is for installing floppy disk. In general, personal computers or server computers have surplus disk slots.

Therefore, the object of the present invention is to install a computer card reader adapting rack to the surplus disk slot without altering the structures of the casing and slots of computers. Thereby, external card reads are unnecessary to be installed.

To achieve above object, the present invention provides a computer card reader adapting rack for installed a card reader so as to read data write data and thus the computer card reader adapting rack is used as a standard device of a computer. The computer card reader adapting rack comprises a support seat, a card reading circuit element, a fixing panel, and an upper cover. The support seat is a box having a size like a 3.5 inches floppy disk. A front side of the support seat is fixed with a panel having a memory slot. An upper side of the support seat is fixed with an upper cover. Moreover, the support seat are installed with respective auxiliary frames and the front side of the support seat has a connecting plate having a window for combining the panel, thereby, the computer card reader adapting rack is used at one of 5.25 disk slots and 3.5 inches disk slots.

The various objects and advantages of the present invention will be more readily understood from the following detailed description when read in conjunction with the appended drawing.

### BRIEF DESCRIPTION OF THE DRAWINGS

FIG. 1 is an exploded perspective view of the computer card reader adapting rack of the present invention.

FIG. 2 is a perspective view of the computer card reader adapting rack of the present invention.

FIG. 3 is an exploded perspective view of the computer card reader adapting rack which is installed with an auxiliary frame.

FIG. 4 is a perspective view of the computer card reader adapting rack which is installed with an auxiliary frame.

### DETAILED DESCRIPTION OF THE INVENTION

In order that those skilled in the art can further understand the present invention, a description will be described in the following in details. However, these descriptions and the appended drawings are only used to cause those skilled in the art to understand the objects, features, and characteristics of the present invention, but not to be used to confine the scope and spirit of the present invention defined in the appended claims.

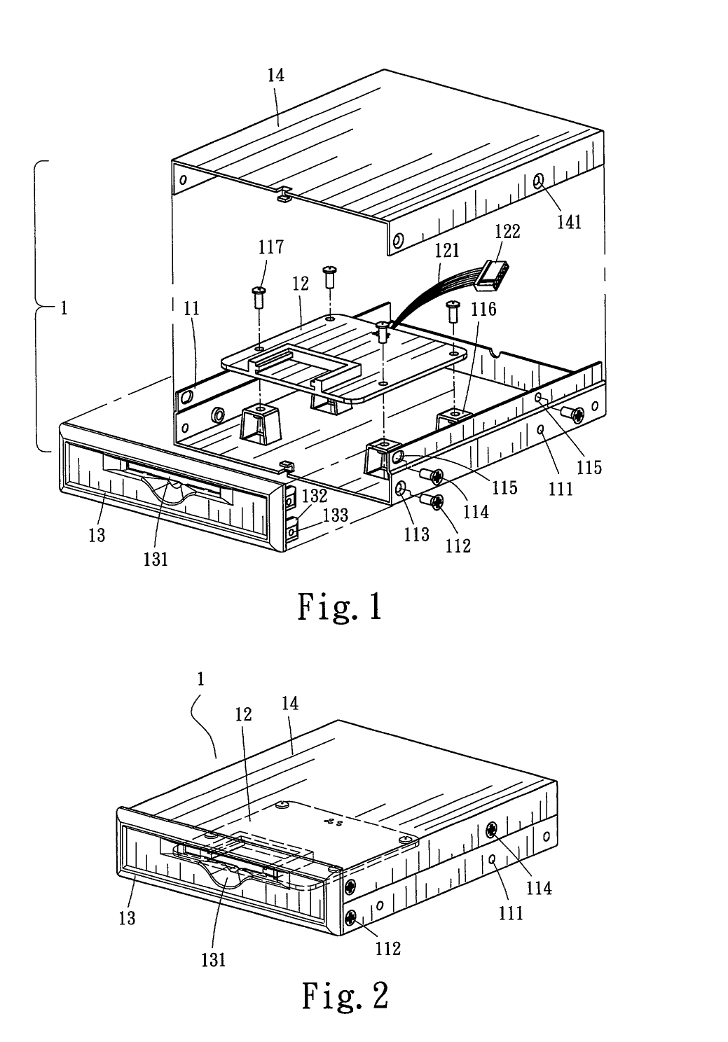

Referring to FIGS. 1 and 2, the exploded perspective view and the assembled perspective view of the computer card reader adapting rack of the present invention is illustrated. The computer card reader adapting rack 1 mainly includes a support seat 11, a card reading circuit element 12, a fixing panel 13, and an upper cover 14.

The support seat 11 is a box having a size like a 3.5 inches floppy disk. The two sides of the support seat 11 have threaded holes 111 for being screwed into a disk slot in the casing of a mainframe of a computer, screw holes 113 for fixing the panel 13 by screws 13, and screw holes 115 for being screwed to the upper cover 14 of the screws 114.

The inner upper surface of the support seat 11 has a plurality of support bases 116. A card reading circuit element 12 can be fixed on the support bases 116 through screws 117. A distal end of the electric wire 121 of each screw 117 is a terminal 122 which is connected to a computer mother board. A front side of the support seat 11 has a panel 13 with a memory slot 131 thereon. The panel 13 is fixed to the support seat 11 by two extending blocks 132 at two sides and the screws 112 which passes through the threaded holes 133 of the extending blocks 132.

An upper cover 13 covers the support seat 11 and screws 114 penetrate through the penetrating holes 141 thereof and then screw into the screw holes 115. Thereby, the computer card reader adapting rack 1 of the present invention can be placed in a 3.5 inches disk slot of a general computer.

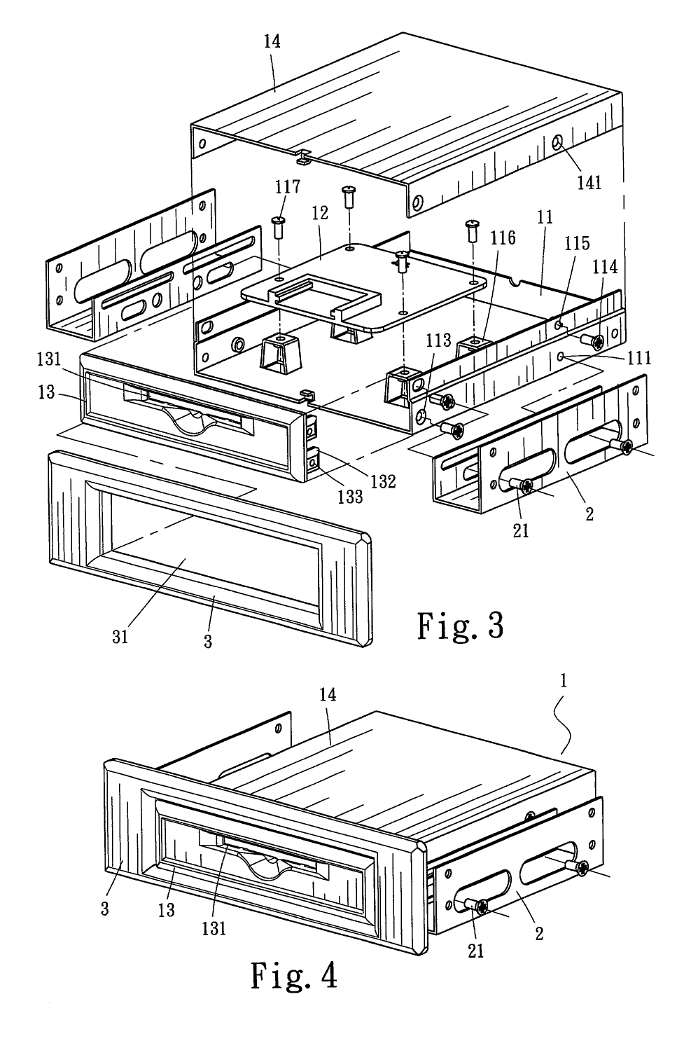

Referring to FIGS. 3 and 4, for installing the computer card reader adapting rack 1 of the present invention to a 5.25 inches disk slot of a general computer; a set of auxiliary frames 2 capable of appending to two sides of the support seat 11 is added, which is assembled with the support seat 11 through screws 21. A connecting plate 3 has a window 31 for combining the panel 13, thereby, the present invention being used at disk seats of 5.25 inches and 3.5 inches.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A The computer card reader adapting rack comprising a support seat, a card reading circuit element, a fixing panel, and an upper cover; characterized in that:
the support seat is a box having a size like a 3.5 inches floppy disk; a front side of the support seat being fixed with a panel having a memory slot; an upper side of the support seat being fixed with an upper cover; wherein the support seat is placed in a 3.5 inches disk slot in a casing of a mainframe of a computer.

2. The computer card reader adapting rack as claimed in claim 1, wherein two sides of the support seat are installed with respective auxiliary frames and the front side of the support seat has a connecting plate has a window for combining the panel, thereby, the computer card reader adapting rack is used at one of 5.25 disk slots and 3.5 inches disk slots.
